(19) United States
(12) Patent Application Publication
(10) Pub. No.: US 2025/0391632 A1
(43) Pub. Date: Dec. 25, 2025

(54) CREATING AN ELECTRIC FIELD WHEN PROCESSING A LITHOGRAPHY OBJECT

(71) Applicant: Carl Zeiss SMT GmbH, Oberkochen (DE)

(72) Inventors: Michael Budach, Hanau (DE); Daniel Schwarz, Aalen (DE); Joerg Petschulat, Jena (DE)

(21) Appl. No.: 19/311,068

(22) Filed: Aug. 27, 2025

Related U.S. Application Data
(63) Continuation of application No. PCT/EP2024/054895, filed on Feb. 27, 2024.

(30) Foreign Application Priority Data
Feb. 28, 2023 (DE) 102023201799.7

(51) Int. Cl. H01J 37/28; G03F 1/22; H01J 37/02; H01J 37/20; H01J 37/305

(52) U.S. Cl. CPC H01J 37/28; G03F 1/22; H01J 37/026; H01J 37/20; H01J 37/3053; H01J 2237/0475; H01J 2237/2007; H01J 2237/24564; H01J 2237/2817

(57) ABSTRACT

The invention relates to interacting, with a particle beam, with an optical lithography object, comprising: application of a first voltage to the object with respect to a reference potential, in order to influence the particle beam. The invention also relates to a testing of a positionable contact element, comprising: provision of a particle beam with a predetermined particle beam current on an object; determination of a contact quality of the positionable contact element based at least in part on the particle beam current and an electric current which flows through the positionable contact element.

### CROSS-REFERENCE TO RELATED APPLICATIONS

This application is a continuation of and claims benefit under 35 U.S.C. § 120 from PCT Application PCT/EP2024/054895, filed on Feb. 27, 2024, which claims priority from German Application 10 2023 201 799.7, filed on Feb. 28, 2023. The entire contents of each of these earlier applications are incorporated herein by reference.

### TECHNICAL FIELD

The present invention relates to a processing of an object, e.g. a lithography object, using a particle beam, and to corresponding methods, a corresponding computer program and a corresponding apparatus.

### BACKGROUND

In the semiconductor industry, increasingly smaller structures are produced on a wafer in order to ensure an increase in integration density. Among the methods used here for the production of the structures are lithographic methods, which image these structures onto the wafer. By way of example, the lithographic methods may comprise, e.g. photolithography, UV lithography, DUV lithography, EUV lithography, x-ray lithography, nanoimprint lithography, etc. In the process, lithography usually makes use of masks (e.g., photomasks, exposure masks, reticles, stamps in the case of nanoimprint lithography, etc.), which comprise a pattern for imaging the desired structures onto a wafer, for example.

As the integration density increases, so do the demands in respect of the mask production (e.g. as a result of the accompanying reduction in the structure dimensions on the mask or as a result of the greater material requirements in lithography). Consequently, the production processes for masks become increasingly more complex, more time-consuming and more expensive, with it not always being possible to avoid mask errors (e.g. defects).

It may therefore be necessary to precisely process an object in a predefined work region, e.g. to rectify or repair mask errors on a mask. For example, this may be implemented by way of a particle beam-based processing method, in which a particle beam is used to process the mask in the predefined work region. The particle beam-based processing method may comprise e.g. a particle beam-induced deposition and/or etching. The particle beam-based processing method may also comprise the step of recording an image of the object via the particle beam.

Numerous complex interactions between particle beam and mask may occur during the processing. However, these interactions may influence the processing method, with the result that the latter might not always be implemented in optimal fashion.

The problem addressed by the present invention is therefore that of specifying methods and apparatuses which provide improved options for processing objects (e.g. for lithography).

### SUMMARY

This general aspect is at least partly achieved by the various aspects of the present invention.

A first aspect of the invention relates to a method of processing a lithography object with a particle beam. The method may comprise: application of a first voltage to the object with respect to a reference potential, in order to influence the particle beam. The first voltage may comprise e.g. a defined (e.g. predetermined) voltage.

For example, the lithography object may comprise an optical lithography object (e.g. the object might be designed to be exposed to an exposure radiation during the optical lithography). The object for the (optical) lithography may comprise e.g. a mask for a lithographic method. For example, the object may comprise an EUV mask for EUV lithography. However, it is also conceivable that the object comprises a mask for any other optical lithographic method, e.g. for DUV lithography, UV lithography and/or x-ray lithography. For example, the object may comprise a transmissive and/or reflective mask for (optical) lithography. Thus, e.g. the mask may be designed such that the exposure radiation is transmitted by the mask or reflected by the mask during (optical) lithography. It is also conceivable that the lithography object need not necessarily comprise an optical lithography object. For example, the object for the lithography might also be designed for non-optical lithography, e.g. might also comprise a stamp for nanoimprint lithography.

The lithography object might also comprise a mask blank in one example. In the lithographic industry, mask blanks are a known initial material for a mask. For example, the mask blank might not comprise any imaging structures like the mask itself but comprise the layer material of the latter.

The concept of the invention is that of allowing the particle beam to be influenced in a targeted manner by the application of a voltage to the object. This may allow the processing of the object with the particle beam to be able to be additionally adapted by the applied voltage. A further process parameter during the processing of lithography objects can be created by the application of the voltage to the object. Accordingly, the invention can extend the field of application for particle beam-based processing of the object.

In one example, the first voltage can be applied directly to the object, e.g. via direct contact on and/or along a certain contact face and/or contact point connected to a voltage source. Thus, the first voltage can be applied directly to the object, e.g. via a contact face. However, the voltage might also be applied to the object substantially via a point contact.

By way of example, the interaction of the particle beam with the object might be altered by the application of the first voltage. This change might influence the particle beam, possibly enabling e.g. a targeted adaptation of a particle beam-based processing method for the object. For example, this may lead to an optimized process control for a particle beam-based processing method.

In known approaches, the mask is attached (substantially fixed in place) to a holder and exposed to the particle beam, e.g. during mask repair. However, no voltage able to influence the incident particle beam in targeted fashion is applied to the mask in the process. For example, this may be problematic during a repair with a particle beam comprising charged particles. An unwanted interaction between mask and object may arise in such a case. This is because the charged particles of the particle beam might cause (e.g. local) charging of the object. This charging may cause an electric field that is able to interact with the particle beam in a bothersome manner. For example, the electric field may lead to an unwanted deflection of the particle beam, with the result that the latter is not incident on the object at a desired target position.

At best, known approaches are based on the passive suppression of this electric field (caused by the particle beam) or on at least partial shielding of the particle beam therefrom. For example, this can be implemented by way of a shielding element which is attached at a certain distance from the surface of the object. For example, the shielding element might be attached in the direct vicinity of the object and have an opening through which the particle beam is able to be incident on the object. For example, the shielding element can be electrically conductive such that an electric field emanating from the object is substantially suppressed on the side of the shielding element facing away from the object. Hence, the interaction of the electric field can be restricted to a (small) region between the object and shielding element (i.e. to a region on the object-facing side of the shielding element).

Thus, known approaches are directed at best to a passive suppression of an electric field which emanates from the object. The concept of the inventors can be interpreted as taking an opposing approach, in which an electric field precisely is actively applied to the object by way of the first voltage. In this respect, the insight of the inventors was hampered by the fact that, at best, all previous approaches taught that during the processing of the lithography object, electric fields which emanate from said object are disadvantageous as a matter of principle and should be actively avoided.

In one example, the particle beam of the method of the first aspect comprises a particle beam with charged particles. The particle beam can comprise e.g. an electron beam. However, it is also conceivable that the particle beam can comprise an ion beam (e.g. comprising positively and/or negatively charged ions). In one example, the particle beam described herein can be used for the particle beam-based (or particle beam-induced) processes described herein.

For example, the first voltage can be applied by way of a voltage source. For example, the voltage source may comprise a voltage source unit which e.g. may comprise an appropriate circuit in order to be able to provide the first voltage at the object.

In one example, the application of the first voltage causes an electric potential in a vicinity of a point of incidence of the particle beam. The point of incidence may comprise a local point and/or a local region on the object. Thus, the invention is not restricted to applying merely a first voltage to the object. Instead, the first voltage can be applied such that an electric potential is present locally-in the vicinity of the point of incidence of the particle beam. For example, the first voltage can be applied in such a way that the electric potential in the vicinity of the point of incidence of the particle beam brings about an electric field which causes an interaction with the particle beam and hence influences the latter.

In one example, the first voltage can be applied to a certain position on the object to ensure that an electric potential which is able to influence the particle beam is also present in the vicinity of the point of incidence of the particle beam.

In one example, the first voltage may comprise a value ensuring that the vicinity of the point of incidence of the particle beam contains an electric potential able to influence the particle beam there. For example, the first voltage can be greater than a predetermined threshold value voltage of the first voltage. For example, the predetermined threshold value voltage may be based on a simulation and/or experimental analyses.

In one example, the electric potential may comprise e.g. a negative electric potential. However, it is conceivable that the electric potential may also comprise a positive electric potential.

In one example, the electric potential in the vicinity of the point of incidence of the particle beam may have the same polarity as the applied first voltage. For example, if the first voltage is negative, then the electric potential in the vicinity of the point of incidence of the particle beam can also be negative (e.g. essentially negative charge carriers may be located at the point of incidence). For example, if the first voltage is positive, then the electric potential in the vicinity of the point of incidence of the particle beam can also be positive (e.g. essentially positive charge carriers may be located at the point of incidence).

In one example, the vicinity (described herein) of the point of incidence of the particle beam may comprise a predetermined work region. The predetermined work region may comprise e.g. a local region of the object. For example, the work region may comprise a pixel raster, with the particle beam scanning over the pixels of the pixel raster (at least in part) when processing the object. The pixel raster may comprise e.g. a repair shape, wherein the lithography object should be repaired within the repair shape by use of the particle beam.

In one example, influencing the particle beam comprises a deceleration of the particles in the particle beam and/or a reduction in a landing energy of the particles in the particle beam. Thus, the first voltage can be applied such that there is a deceleration of the particles in the particle beam and/or a reduction in a landing energy of the particles in the particle beam.

For example, the particles in the particle beam being decelerated by forces emanating from the object or reducing their landing energy on the object may be advantageous for the processing of the object. For example, this may inter alia allow the particles to penetrate into the object to a shallower depth (than without the application of the first voltage), and this may be advantageous for the processing of the object.

Decelerating the particles and/or reducing the landing energy thereof may be advantageous for e.g. a particle beam-induced deposition and/or etching at the point of incidence of the particle beam (as described herein) or may influence the particle beam-induced deposition and/or etching as a further process parameter. Thus, the invention can also be used as a further setscrew for adapting particle beam-induced processes. Further, decelerating the particles and/or reducing the landing energy might also be advantageous if the processing with the particle beam comprises the recording of an image of the object (with the aid of the particle beam). For example, the quality of the image recording may be improved or adapted by decelerating the particles and/or reducing the landing energy.

The invention may also extend or facilitate particle beam control. For example, it may be advantageous for technical reasons to provide the particles of the particle beam with a (comparatively) high acceleration and/or high energy. For example, this may be necessary to enable a certain property of the particle beam (e.g. a certain resolution) or to suitably control the particle beam (e.g. facilitate focusing). However, it may be advantageous for the processing of the object (as described herein) that the particles are incident on the object with a (comparatively) low acceleration and/or low energy.

However, known approaches for processing lithography objects can offer only one of these two advantageous effects (i.e. either an advantageous control of the particle beam in the case of a comparatively high particle acceleration or an advantageous incidence of the particles on the object in the case of a comparatively low particle acceleration). By contrast, the invention is able to combine the advantages of these two (actually competing) effects. The invention can implement a comparatively high (initial) particle acceleration since the particles are decelerated prior to incidence on the object as a result of the application of the first voltage. Thus, the application of the first voltage means that it is no longer mandatory to resort to a low (initial) acceleration voltage in order to ensure a low landing energy of the particles, at which the particle beam would e.g. be more difficult to control.

In one example, influencing the particle beam may also comprise an acceleration of the particles in the particle beam and/or an increase in a landing energy of the particles in the particle beam. Thus, the first voltage can also be applied such that there is an acceleration of the particles in the particle beam and/or an increase in a landing energy of the particles in the particle beam.

In one example, the first voltage comprises a negative or positive voltage with respect to the reference potential. In one example, the polarity of the electric potential (described herein) in the vicinity of the point of incidence of the particle beam may also correspond to the polarity of the first voltage. For example, given a negative first voltage there can be a negative electric potential in the vicinity of the point of incidence of the particle beam.

In one example, the reference potential may comprise a reference potential with respect to an extraction voltage of the particle beam. For example, the method can be carried out using an apparatus which comprises a particle beam source for creating the particles of the particle beam. The particles from the particle beam source can be emitted in the form of a particle beam in the direction of the object by way of an extraction voltage with respect to the reference potential. Thus, the first voltage can be applied with respect to this reference potential. It is also conceivable that the reference potential serves as reference potential for further voltages required to monitor and/or control the particle beam.

In one example, the first voltage can differ from the reference potential. For example, the reference potential may comprise an earth potential, which is assigned a potential of zero. Thus, the first voltage can differ from zero (e.g. be greater than or less than zero) in such an example.

In one example, the first voltage can be applied to a side (e.g. a front side) of the object where one or more imaging structures of the object are arranged.

In one example, the first voltage can be applied to a position of the object from where an electrically conductive connection leads to a vicinity of a point of incidence of the particle beam. For example, the method might comprise a determination as to whether an electrically conductive connection is present from the vicinity of the point of incidence to the position of the object where the first voltage is applied.

For example, the vicinity of the point of incidence of the particle beam can be considered position B and the position of the object where the first voltage is applied can be considered position A. The electrically conductive connection may encompass a connecting path with a comparatively high electrical conductivity being present between position B and position A. For example, the electrically conductive connection may comprise a connecting path comprising a metal and/or a semiconductor. For example, the electrically conductive connection may also comprise a connecting path comprising one or more materials that have a conductivity with a value corresponding to a conductivity of a metal and/or semiconductor.

In one example, the electrically conductive connection comprises, at least in part, a capping layer of the object, which may be adjoined by one or more imaging structures of the object. For example, the object may comprise a lithography mask. The mask may comprise e.g. a capping layer, to which (one or more) imaging structures may be attached. For example, the imaging structures may also be referred to as pattern elements. The capping layer might be constructed from e.g. an electrically conductive material. In one example, the capping layer may comprise e.g. one or more metals and/or semiconductors. In one example, the capping layer may comprise e.g. ruthenium. In one example, the capping layer may comprise e.g. one or more of the following materials: ruthenium, chromium, chromium nitride (and/or compounds or alloys of these materials). In one example, the capping layer may for example comprise one of the following materials: a diamond-like carbon (DLC), boron nitride (e.g. BN), rhodium, boron carbide (e.g. B₄C), silicon nitride (e.g. Si₃N₄), silicon carbide (e.g. SiC), palladium, titanium nitride (e.g. TiN), magnesium fluoride (e.g. MgF₂), lithium fluoride (e.g. LiF), C₂F₄, Teflon, gold (and/or compounds or alloys of these materials).

In one example, the electrical connection may comprise, at least in part, a layer of an imaging structure of the object. For example, the layer of an imaging structure may comprise a metal and/or a semiconductor. Thus, the electrical connection need not necessarily be implemented via the capping layer but may also comprise a part of an imaging structure. For example, an imaging structure may comprise tantalum and/or chromium. However, other metals (and/or semiconductors) are also conceivable as the material of the imaging structure. All that may be relevant in this context for the concept of the invention is that the imaging structure comprises a comparatively high conductivity (e.g. like a metal and/or semiconductor).

In one example, the position of the object where the first voltage is applied comprises a part of a capping layer of the object, which may be adjoined by one or more imaging structures of the object. For example, the first voltage can be applied via a contact with the capping layer of the object. For example, a contact element coupled to a voltage source may be in contact with the capping layer of the object. Subsequently, the first voltage with respect to the reference potential can be applied by way of the voltage source. For example, the contact element can be brought into contact with the capping layer in a first step. Then, the first voltage can be applied via the contact element (e.g. the first voltage can be increased incrementally) in a second step.

It may be predetermined in one example that, from the contact position of the contact element on the capping layer, the latter leads (without interruption) to a vicinity of a point of incidence of the particle beam on the object. As a result, it is possible to ensure that the capping layer (as described herein) may act as an electrical connection. For example, the object may comprise a mask (or a mask blank). In that case, whether the capping layer would lead (without interruption) from the contact position of the contact element on the capping layer to the vicinity of the point of incidence of the particle beam can be ascertained from the corresponding specification for the object (e.g. its layer structure).

Figuratively speaking, the capping layer of one example can be considered to be an (e.g. continuously) electrically conductive plate. As soon as a first voltage is applied to the electrically conductive plate, the assumption can essentially be made that the first voltage drops over the entire electrically conductive plate. For example, it is thus possible to ensure that the first voltage can interact with a particle beam incident on the electrically conductive plate at any point on the latter. Further, it is for example also possible to ensure that the first voltage can be coupled to any imaging structure adjoining the electrically conductive plate.

In one example, the position of the object where the first voltage is applied comprises a part of an imaging structure of the object, wherein the imaging structure may adjoin a capping layer of the object. For example, the first voltage can be applied via a contact with an imaging structure of the object. For example, a contact element coupled to a voltage source may be in contact with an imaging structure of the object. Subsequently, the first voltage with respect to the reference potential can be applied by way of the voltage source. For example, the contact element can be brought into contact with the imaging structure in a first step. Then, the first voltage can be applied via the contact element (e.g. the first voltage can be increased incrementally) in a second step.

For example, the first voltage can be coupled (at least in part) into the capping layer of the object, which may adjoin the imaging structure, by way of the application of the first voltage to the imaging structure. For example, as described herein, the coupling may be brought about by way of an electrically conductive connection between the imaging structure and the capping layer. For example, the imaging structure may comprise a material with a comparatively high electrical conductivity such that coupling is rendered possible. As described herein, the capping layer of one example can be considered to be an (e.g. continuously) electrically conductive plate.

Accordingly, the entire electrically conductive plate can, for example, also be set at the first voltage as soon as a first voltage is applied to the imaging structure. For example, it is thus possible to ensure that the first voltage can interact with a particle beam incident on the electrically conductive plate at any point on the latter.

In one example, the position of the object where the first voltage is applied may also comprise a part of a (not necessarily imaging) structure of the object, wherein the (not necessarily imaging) structure may adjoin a capping layer of the object. For example, a reference structure and/or an alignment structure (e.g. an overlay/alignment structure) of the object, which may adjoin the capping layer of the object, may also be contacted.

In one example, the first voltage is applied via a positionable contact element. For example, the positionable contact element may comprise an electrically conductive contact element which may be positioned at one or more positions of the object (e.g. one or more contact positions). By way of the positionable contact element, it is possible for example to contact the object at one or more contact positions, with the result that the first voltage can be applied to the corresponding one or more contact positions. In one example, the contact element can be positioned at two or more positions of the object (e.g. two or more contact positions). As described herein, the positionable contact element may be coupled to a voltage source which for example is able to provide the first voltage.

In one example, the positionable contact element may comprise a beam element. For example, the positionable contact element may comprise a leaf spring (also referred to as cantilever). For example, the positionable contact element may comprise an electrically conductive probe. In one example, the positionable contact element may comprise a probe for atomic force microscopy (e.g. an AFM probe). For example, the probe may be adapted to the effect of allowing the voltages mentioned herein to be applied (e.g. without damaging the probe).

In one example, the method further comprises: provision of the particle beam with a predetermined particle beam current; determination of a contact quality of the (positionable) contact element based at least in part on the particle beam provided and an electric current which flows through the contact element. For example, the example can be applied to verify whether the positionable contact element is in fact in contact with the object. Further, it is also possible to make a statement about the degree or quality of contacting; for example whether a sufficient contact (e.g. a good contact) is present, which can reliably ensure an application of the first voltage. For example, the contact quality can be determined before the first voltage is applied.

For example, the (positionable) contact element can be coupled to an ammeter configured to measure the electric current flowing through the contact element.

In one example, the determination of the contact quality may comprise a provision of a particle beam on the object with a predetermined particle beam current. For example, it is possible to provide a particle beam current I_{T}. For example, an electron beam with an electron current of I_{T} can be provided as particle beam. Further, the determination of the contact quality may comprise a measurement of the electric current through the contact element using the ammeter (e.g. measuring a contact element current I_{K}). For example, the contact element current I_{K} can be measured while the particle beam with the particle beam current I_{T} is provided on the object. Measuring the current I_{K} allows a statement to be made about the degree to which the particle beam current I_{T} provided induces a current flow over the object through the contact element. This can be used to determine the contact quality. For example, if (good) contact is present, then the current flow induced (by the particle beam) in the object can flow away through the contact element without substantial obstacles. For example, if a comparatively poor contact is present, then a comparatively smaller current flow through the contact element must be expected. For example, if no contact is present, then the charges induced (by the particle beam) in the object cannot flow away through the contact element (and cause a contact element current I_{K}).

In one example, a particle beam at a predetermined energy can be provided for the determination of the contact quality. For example, it is conceivable that, even though the contact element is in fact in (good) contact with the object, a state with lower or no current flow through the contact element might arise while the object is irradiated with the particle beam. For example, it is conceivable that the current of the incoming particle beam and a current of secondary electrons emanating from the object compensate one another. For example, such a case can be avoided if a predetermined energy of the incident particle beam is used, with the result that a poor (or no) contact can also be assumed in the case of a low or no current flow through the contact element.

For example, the energy of the particle beam can be chosen so that the secondary electrons and backscattered electrons emitted by the object do not compensate the incoming particle beam.

For example, the determination of the contact quality may be based on a relationship between the measured contact element current I_{K} and a predetermined threshold value I_{TH}. For example, a sufficient (or good) contact quality might be determined if the contact element current is greater than the predetermined threshold value (I_{K}>I_{TH}). For example, an insufficient (or poor) contact quality might be determined if the contact element current is less than the predetermined threshold value (I_{K}<I_{TH}). In one example, the predetermined threshold value I_{TH} may depend on the predetermined particle current I_{T}. For example, this relationship may be determined on the basis of simulations and/or experimental analyses.

In one example, the position of the object where the first voltage is applied is on a side of the object not containing any imaging structures and/or on a substrate side of the object. Thus, the first voltage need not necessarily be applied to a side of the object containing (or possibly containing) imaging structures.

In one example, the particle beam can be used to process a side of the object on which imaging structures are situated (e.g. for repairing the imaging structures, as described herein). For the purpose of influencing the particle beam in this context, the first voltage can also be applied to the opposite side (e.g. to the side of the object not containing any imaging structures). Usually, the side of the object not containing any imaging structures may also be considered to be the substrate side since the substrate of the object is (usually) situated on this side. For example, the substrate of the object may comprise a material suitable for acting as the lower side (e.g. the support of the object) during its processing. For example, the substrate may comprise a material with little thermal expansion and/or an EUV mask substrate.

In one example, the first voltage is applied via an electrically conductive object holder, to which the object is attached. For example, the object holder may comprise a positionable object holder suitable for positioning the object in one or more degrees of freedom. For example, the object holder might displace the object in a (two-dimensional) plane and/or also adjust its height (e.g. along an optical axis of the particle beam). For example, the object holder can be configured to fix (or hold) a side of the object not containing any imaging structures or a substrate side of the object. Thus, the side not containing any imaging structures may rest against the object holder.

For example, the object holder may be coupled to a voltage source which can provide the first voltage. In one example, the object holder may comprise a chuck (e.g. an electrostatic chuck, a vacuum chuck and/or any other type of chuck). In addition to securing the object, the chuck may comprise e.g. an electrode which can be used to provide the first voltage at the object.

In one example, the method further comprises: application of a second voltage to an electrode element with respect to the reference potential, wherein the electrode element is positioned between the object and a source of the particle beam and comprises an opening through which the particle beam can be incident on the work region. For example, the electrode element can be positioned such that the particle beam can pass therethrough and subsequently be incident on the object. The application of the second voltage can create a further degree of freedom for influencing the particle beam when processing the object.

In this case, the position of the electrode element can be related to the beam path of the particle beam. For example, the electrode element may be arranged between a particle beam source and the object in relation to an optical axis of the particle beam path. For example, the particle beam may be adaptable by way of a particle beam optical unit arranged in the particle beam path. For example, the particle beam optical unit may comprise one or more particle-optical elements and/or beam deflection elements for adaptation purposes, with the result that the particles may experience e.g. focusing and/or a deflection.

In one example, the electrode element can be positioned such that there is no (further) particle-optical element and/or no (further) beam deflection element between the electrode element and the object. For example, the electrode element can be situated substantially downstream of the particle beam optical unit in the particle beam path, with the result that the particle beam has essentially already experienced the effects of the one or more particle-optical elements and/or one or more beam deflection elements. In this example, the particle beam can thus be adapted further by way of the second voltage after the particle beam has passed through the (known) particle beam optical unit.

In one example, the second voltage can differ from the reference potential. For example, the reference potential may comprise an earth potential, which is assigned a potential of zero. The second voltage can differ from zero (e.g. be greater than or less than zero) in such an example.

In one example, the second voltage can be applied so as to adapt an electric field between the object and the electrode element. For example, the second voltage can be applied to adapt the electric field emanating from the object. Thus, the second voltage can be applied for the purpose of adapting the electric field of the object caused by the application of the first voltage.

This example takes account of the fact that several phenomena may occur as a result of the application of the first voltage at the object. These can be addressed specifically by the second voltage, with the result that it is possible to avoid uncontrolled effects. Further, it is possible to create a further degree of freedom during the complex particle beam processing of objects.

For example, application of the first voltage to the object may increase the probability of critical electric field strengths also being created. For example, these may lead to a flashover (e.g. an electrical breakdown) at the object. For example, critical field strengths may arise in particular at the geometries of the voltage-carrying (imaging) structures of the object (e.g. at corners and/or edges of the structures where strong electric fields may arise). Under certain circumstances, the flashovers may lead to damage on the object. The influence of this effect can be controlled or avoided in a targeted manner by the application of the second voltage (as described herein).

Likewise, the geometry of the (imaging) structures or the topography of the object may lead to a distortion of the electric field above the object. Thus, the application of the first voltage may lead to an inhomogeneous field above the object. This may lead to the particle beam not always being reliably influenced in the same way over the entire object. The influence of this effect can likewise be controlled or avoided in a targeted manner by the application of the second voltage (as described herein).

Additionally, a mechanical tilt of the object (e.g. with respect to the optical axis of the particle beam path or an objective of the particle beam optical unit) may lead to an electric field strength gradient. The influence of this effect can be controlled or avoided in a targeted manner by the application of the second voltage (as described herein).

In one example, the application of the second voltage may comprise the second voltage substantially corresponding to the first voltage. For example, the first voltage may comprise a value of U1 with respect to the reference potential. In this example, the second voltage may in essence likewise comprise U1 with respect to the reference potential. Consequently, the electrode element and the object may be at substantially the same potential (e.g. U1). Using this setting, it is possible for example to create a space between object and electrode element which (globally) is substantially free from an electric field. However, this space continues to be at an electric potential that is able to influence the particle beam.

In this example, the aforementioned (field-induced) effects arising due to the application of the first voltage can thus be avoided by the creation of a substantially field-free space between object and electrode element. However, at the same time, the particle beam can still be influenced in a targeted manner via the first and second voltage, for example to decelerate the particles and/or reduce their landing energy.

In one example, the application of the second voltage comprises the second voltage being different from the first voltage.

For example, the first voltage may comprise a value of U1 with respect to the reference potential. In this example, the second voltage may comprise a value U2 with respect to the reference potential, with U2 differing from U1. For example, U2 might be greater than U1 (U2>U1) or U2 might be less than U1 (U2<U1).

In one example, the second voltage may differ from the first voltage but correspond to a proportional (comparatively small) change in voltage vis-à-vis the first voltage. For example, the difference between the second voltage and the first voltage might comprise 20% of the absolute value of the first voltage, 10% of the absolute value of the first voltage, 5% of the absolute value of the first voltage and/or 1% of the absolute value of the first voltage.

In an example in which the second voltage is applied, the first voltage might also correspond to the reference potential. For example, the reference potential may comprise an earth potential, which is assigned a potential of zero. In such an example, the first voltage might be zero, wherein the second voltage may have a value unequal to zero (e.g. greater than or less than zero). Effectively, it is thus also possible to merely apply a voltage to the electrode element.

In one example, the electrode element comprises a shielding element serving to shield the particle beam from an electric field which may emanate from the object when the latter is processed by the particle beam. Shielding elements are known elements within the scope of processing lithography objects. However, to date, these were used at best for passive shielding of electric fields of the object which were caused (parasitically) by charges in the object incorporated in the object by particle beam bombardment. As described herein, a shielding element might be attached e.g. in the direct vicinity of the object and have an opening through which the particle beam is able to be incident on the object. Thus, such a shielding element can be repurposed in this example of the invention and can be actively set at a second voltage in order (as electrode element described herein) to influence the particle beam.

In one example, the shielding element may comprise a shielding element as described in DE102020124307A1. In this case, this shielding element can be adapted in accordance with the present invention (e.g. be coupled to a voltage source). In one example, the shielding element may comprise a shielding element as described in EP 1587128. In this case, this shielding element can be adapted in accordance with the present invention (e.g. be coupled to a voltage source).

In one example, the method further comprises: creation of a material on the object and/or removal of a material of the object based at least in part on the particle beam, preferably using at least one gas provided on the object. For example, the creation and/or removal of a material can be implemented purely by way of the particle beam (without necessarily requiring a gas). For example, this may also comprise milling with the particle beam.

In one example, the creation and/or removal of a material of the object can be implemented at least in part on the basis of the particle beam and at least one gas provided on the object. For example, this may comprise a particle beam-induced deposition and/or a particle beam-induced etching. For example, the particle beam-induced deposition may comprise an electron beam-induced deposition. The particle beam-induced etching may comprise an electron beam-induced etching, for example. In these processes, at least one gas required e.g. for the corresponding reaction may be provided on the object. For example, the gas may comprise a deposition gas (e.g. a metal carbonyl). For example, the gas may also comprise an etching gas (e.g. a halogen-based etching gas).

Thus, the influencing of the particle beam described herein can also be used as a process variable during a particle beam-induced deposition and/or etching. For example, the first and/or second voltage may be applied during a particle-beam induced process, in order to adapt the process.

In one example, the method further comprises: recording of a particle beam image of the object based at least in part on the particle beam. The influencing of the particle beam described herein may thus also be used as a factor when recording an image of the object (e.g. for an electron beam image).

In one example, the method is used for repairing a defect of the object. For example, the method described herein can be used for imaging purposes during the repair. For example, recording an image at certain steps may be necessary within the scope of the repair. For example, it may be useful here to influence the particle beam as described herein.

For example, the method described herein can be used during the particle beam-induced creation and/or removal of material for the purpose of repairing a defect in the object. For example, the object may comprise a lithography mask, wherein the repair of the defect may accordingly comprise a mask repair. For example, the repair may comprise the repair of locations at which material of the object is missing and/or at which excess material is present, even though this should not be the case according to the specification.

For example, the method of the first aspect may be considered to be a method for repairing a lithography object using a particle beam.

For example, missing material in the object (e.g. the mask) can be repaired by way of a particle beam-induced deposition, in which the particle beam is influenced using a method as described herein. For example, excess material in the object (e.g. the mask) can be repaired by way of a particle beam-induced etching, in which the particle beam is influenced using a method as described herein.

In one example, the object comprises an EUV lithography mask. The EUV lithography mask might also be referred to as EUV mask herein. For example, the EUV mask may comprise a substrate, which is adjoined by a reflective multilayer stack. For example, a capping layer may adjoin the reflective multilayer stack. One or more imaging structures may adjoin the capping layer.

In one example, there might be an electrically conductive connection between substrate and the capping layer. However, this need not necessarily be the case.

However, it is also conceivable that the first aspect is used in other processing steps. For example, this aspect could also be used when merely performing an examination (with the aid of the particle beam). In addition or as an alternative, it is also conceivable that the first aspect is used for objects not necessarily being lithography objects but being general samples that can be processed and/or examined using a particle beam.

A second aspect relates to a method for testing a positionable contact element. The method of the second aspect comprises: provision of a particle beam with a predetermined particle beam current on an object; determination of a contact quality of the positionable contact element (with the object) based at least in part on the particle beam provided and an electric current which flows through the positionable contact element.

As an alternative or in addition, the contact quality could also be implemented with the aid of an electrical capacitance measurement between the contact element and the object and/or a determination of a differential resistance at or around a voltage of 0 V. It is also possible to use two or more contact elements as a matter of principle. Then, the contact quality could alternatively or additionally also be implemented based at least in part on a four-point measurement of the sheet resistance or an electric current between the two or more contact elements.

In the process, the features of the first aspect described herein may accordingly also be comprised in the method of the second aspect. For example, a feature of the example of the first aspect which also relates to a determination of a contact quality of a (positionable) contact element based at least in part on the particle beam current and an electric current which flows through the contact element may apply to the method of the second aspect. However, the method of the second aspect does not require a mandatory application of a first voltage within the scope of the method. For example, the method of the second aspect can be considered to be a calibration step, which might also occur during the method of the first aspect. However, this calibration step can also be pursued separately (e.g. with a time offset).

In principle, the method of the second aspect may for example also be used during the processing of a lithography object. For example, the positionable contact element may comprise an atomic force microscope probe, which is used to process the object. For example, the method of the second aspect can be used to test the atomic force microscope probe, for example whether the latter has a certain contact quality (with the object) at a given position (as described herein). It is also conceivable that the positioning of the atomic force microscope probe can be calibrated using the method.

In one example, the method of the second aspect is not necessarily restricted to a lithography object. Rather, the method of the second aspect may also serve for any object where a contact element is in contact with an object (and a particle beam is available). For example, this may be useful within the scope of the precise processing (or examination) of objects which rely on suitable contacting.

A third aspect relates to a computer program comprising instructions which, when executed by a computer, are able to implement the (automated) performance of a method of the first and/or second aspect by a computer and/or an apparatus.

The features for the method of the first and/or second aspect described herein may be comprised accordingly in the computer program. The features (and also examples) of the methods specified herein may also be applied or applicable correspondingly to the computer program mentioned.

When the computer program is executed, the latter may for example output an instruction comprising the intention (as described herein) of applying a first voltage to the lithography object. In the same way, when the computer program is executed, the latter may for example output an instruction comprising the intention (as described herein) of applying a second voltage to the electrode element.

A further aspect relates to a memory comprising the computer program of the third aspect.

A fourth aspect relates to an apparatus for processing a lithography object using a particle beam, comprising: means for applying a voltage to the object with respect to a reference potential, in order to influence the particle beam.

In some examples, the apparatus comprises a computer unit which causes the apparatus to perform a method of the first and/or second aspect (e.g. based at least in part on an execution of a computer program of the third aspect, which is stored in the computer unit).

The features (and also examples) of the methods specified herein may also be applied or applicable correspondingly to the apparatus mentioned.

For example, the computer unit may comprise a computer, a computing unit, a microprocessor, etc. For example, the computer unit may be communicatively coupled to the components of the apparatus such that a signal output by the computer unit can cause a change in a component of the apparatus.

In one example, the apparatus comprises a memory comprising the computer program of the third aspect. In this example, the computer unit may be able to carry out the computer program. For example, the computer program may be installed on the computer unit and hence on the apparatus (physically/concretely).

In one example, it is also possible that the computer program is stored elsewhere (e.g. in a cloud) and the device merely has means for receiving instructions that arise from executing the program elsewhere. Thus, the computer program can be executed externally (e.g. on an external computer unit, on a server unit, etc.) in this case, wherein the instructions of the computer program are transmitted to the receiving means of the apparatus. The means for receiving the instructions may be communicatively coupled to the computer unit of the apparatus, for example. For example, the receiving means may comprise a reception unit configured to receive and/or process instructions via a wireless and/or wired connection.

For example, the synergy of computer program and corresponding apparatus may allow the method to run in automated or autonomous fashion within the apparatus. Consequently, it is also possible to minimize the intervention, for example by an operator, and so it is possible to minimize both the costs and the complexity when processing (lithography) objects.

In one example, the application means comprises a positionable contact element and/or an object holder and a voltage source coupled to the contact element and/or the object holder. Thus, the voltage source may be electrically connected to the contact element (described herein) and/or the object holder (described herein).

In one example, the voltage source, which is coupled to the contact element and/or the object holder, may be designed to provide the first voltage (described herein).

In one example, the application means may comprise an electrode element (as described herein) and a voltage source coupled to the electrode element.

In one example, the voltage source, which is coupled to the electrode element, may be designed to provide the second voltage (described herein).

In one example, the application means is designed to apply, in terms of absolute value, a maximum voltage of 40 000 V, (preferably) 4000 V, (more preferably) 1000 V, or (most preferably) 100 V to the object with respect to the reference potential. In one example, the application means is designed to apply, in terms of absolute value, a maximum voltage ranging between 100 V and 4 kV. In a further example, the application means is designed to apply, in terms of absolute value, a maximum voltage ranging between 1 kV and 4 kV.

In one example, the device comprises an ammeter coupled to the positionable contact element and/or the object holder, wherein the ammeter is designed to measure a current of (in terms of absolute value) at least 0.5 pA, preferably at least 1 pA, more preferably at least 500 pA, and most preferably at least1 nA through the positionable contact element and/or the object holder.

For example, the ammeter may be designed to measure a corresponding positive and/or negative current.

A fifth aspect relates to an apparatus for testing a positionable contact element, comprising: means for providing a particle beam with a predetermined particle beam current on an object; means for determining a contact quality of the positionable contact element based at least in part on the particle beam current and an electric current which flows through the positionable contact element.

The features (and also examples) of the apparatus of the fourth aspect may also be comprised correspondingly in the apparatus of the fifth aspect (or applied to the latter). Moreover, the apparatus of the fourth aspect may be suitable for example to accommodate and examine and/or process any given object (e.g. with the aid of the particle beam). In a manner analogous to what was described with regards to the apparatus according to the fourth aspect, the apparatus according to the fifth aspect may also comprise a computer unit, with the result that the apparatus may be configured to automatically perform method steps (as described herein).

A sixth aspect relates to a lithography object which was processed using a method according to any of the methods described herein.

A seventh aspect relates to a method for processing a semiconductor-based wafer, comprising: a lithographic transfer of a pattern associated with a lithography object to the wafer, wherein the object has been processed using a method of the aspects described herein. The lithographic transfer may comprise a lithography method for which the object is designed (e.g. EUV lithography, DUV lithography, i-line lithography, etc.). For example, the method of this aspect may comprise a provision of a beam source of electromagnetic radiation (e.g. EUV radiation, DUV radiation, i-line radiation, etc.). This may additionally comprise a provision of a developable lacquer layer on the wafer. The lithographic transfer may also be based at least in part on the radiation source and the provision of the developable lacquer layer. It is possible here, for example, by use of the radiation from the radiation source, to image the pattern onto the lacquer layer (in a transformed form).

It should be mentioned that the features (and also examples) of the methods specified herein may also be applied or applicable correspondingly to the apparatus mentioned. The features (and also examples) of the apparatus that are specified herein may likewise be applied or applicable correspondingly to the methods described herein.

### BRIEF DESCRIPTION OF DRAWINGS

The following detailed description describes technical background information and working examples of the invention with reference to the figures, in which:

FIG. 1 schematically illustrates an EUV lithography mask as a lithography object.

FIG. 2 schematically illustrates an exemplary apparatus of the invention for processing a lithography object.

FIG. 3 schematically shows an application of a first voltage to the lithography object according to the invention.

FIG. 4 schematically shows an application of a first and second voltage to the lithography object according to the invention.

FIG. 5 schematically shows a further example regarding the application of a first and second voltage to the lithography object according to the invention.

FIG. 6 schematically shows a side view of an EUV mask which can be processed according to the invention and a corresponding plan view.

FIG. 7 finally shows, schematically, a further example of an application of a first voltage to the lithography object.

FIG. 8 schematically shows an application of a first voltage to the object, wherein the object holder comprises an electrostatic chuck.

FIG. 9 schematically shows an application of a first voltage to the object via a first exemplary object holder according to the invention.

FIG. 10 schematically shows an application of a first voltage to the object via a second exemplary object holder according to the invention.

FIG. 11 schematically shows a method for testing a positionable contact element according to the invention.

### DETAILED DESCRIPTION

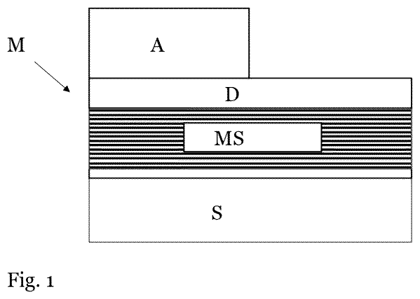

FIG. 1 schematically illustrates an EUV lithography mask M as an exemplary lithography object. Herein, the mask M may also be referred to as EUV mask M. However, as described herein, the aspects of the invention are not restricted to EUV masks M or EUV lithography. The invention may also relate to other lithography objects, for example EUV mask blanks, DUV masks, nanoimprint stamps, etc. (as mentioned herein). For illustrative purposes, the invention is described in detail hereinbelow on the basis of an EUV mask M. However, the term EUV mask M may apply (accordingly) to any lithography object.

The (basic) design of EUV masks M is known within the semiconductor industry. The EUV mask M may comprise a substrate S, for example. A multilayer stack MS may adjoin the substrate S. The multilayer stack MS may comprise a reflective Bragg mirror. For example, the multilayer stack MS may include layers comprising molybdenum and/or silicon. In this case, the multilayer stack MS can be configured to be reflective for the EUV wavelength of EUV lithography. For example, the multilayer stack may be reflective for a wavelength of 13.5 nm.

A capping layer D of the EUV mask M may adjoin the multilayer stack MS. The capping layer D may comprise the properties described herein. For example, the capping layer D may comprise a metal and/or a semiconductor. The capping layer D may also comprise a metal compound, for example. In one example, the capping layer D may include ruthenium. In one example, the capping layer D may also include a material with a conductivity corresponding to the conductivity of a metal (and/or semiconductor).

The capping layer D may be adjoined by an imaging structure A. The imaging structure A may comprise one or more layers. For example, the layers of the imaging structure A may comprise absorbing and/or phase-shifting properties in relation to the wavelength of the EUV lithography. For example, the imaging structure A may comprise (as described herein) a metal and/or a semiconductor. In one example, the imaging structure A essentially comprises one or more metals, with the result that the imaging structure has a comparatively high electrical conductivity. The imaging structure may serve to enable the imaging of a corresponding pattern on a plane (e.g. a wafer plane) by irradiating the EUV mask at the EUV wavelength.

The side of the EUV mask on which the substrate S is situated might also be referred to as substrate side herein. The side of the EUV mask on which the capping layer D (or an imaging structure A) is situated might also be referred to as top side of the EUV mask herein.

It should be mentioned that the described layer structure for an EUV mask may in practice also comprise a substantially more complex layer structure. For example, an EUV mask M may also comprise one or more further layers not mentioned here (e.g. between the layers mentioned herein).

In this case, the EUV mask M can be processed using a method as described herein.

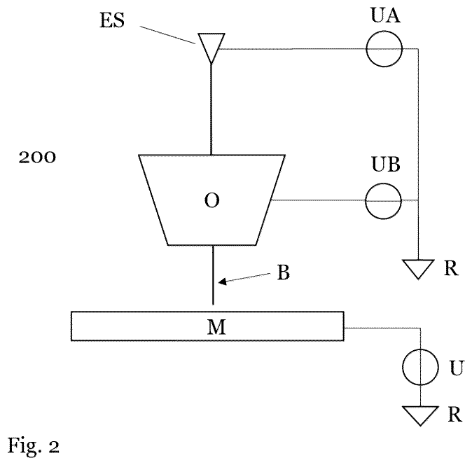

FIG. 2 schematically illustrates an exemplary apparatus 200 of the invention for processing a lithography object using a particle beam B. The apparatus 200 may be configured to apply a voltage U to the EUV mask M in order to influence a particle beam B. In this case, the voltage U can be applied with respect to a reference potential R of the apparatus 200.

The apparatus 200 might be configured to provide an electron beam as particle beam B. For example, the apparatus 200 might comprise an electron source ES (as particle beam source). From the electron source ES, electrons can be accelerated using an acceleration voltage UA. In this case, the electron beam B can be coupled into a particle beam optical unit, for example an objective O. One or more further electrodes able to influence the energy of the electrons may be comprised in the objective O. For example, the electrons of the electron beam B may be additionally influenced by a voltage UB. Further, the apparatus 200 may also comprise one or more particle-optical elements and/or beam deflection elements (as described herein). After leaving the particle beam optical unit (e.g. after leaving the objective O), the electron beam B can be incident on the EUV mask M. The apparatus 200 may for example comprise components of a scanning electron microscope.

As described herein, the concept of the invention is that of applying a voltage U to the EUV mask M. The voltage U can create an electric field, which can interact with the electron beam, at the EUV mask. For example, a negative first voltage U (with respect to the reference potential) can be applied. This may create an electric field, which is able to interact with the negatively charged electrons in the electron beam B, at the EUV mask M. For example, the electric field in the case of a negative voltage U may represent an opposing electric field. The electrons in the electron beam B can be decelerated by the opposing electric field. It is also conceivable that a landing energy of the electrons in the electron beam B on the EUV mask is reduced as a result of the opposing electric field. The application of the voltage U can thus create a further degree of freedom when processing EUV masks M (as described herein). For example, the voltage U might be applied within the scope of recording a scanning electron image of the EUV mask M, in order to adapt the recording. However, the voltage U can also be applied in order to remove and/or create material on the EUV mask.

In one example, the apparatus 200 may comprise one or more storage containers in which process gases can be stored. The apparatus 200 may further comprise a gas injection system, with which the one or more process gases can be provided in a vicinity of the EUV mask M. For example, the apparatus 200 can be configured such that electron beam-induced deposition and/or electron beam-induced etching can be implemented on the EUV mask. The process gases required to this end can be guided, e.g. globally, into the entire chamber in which the EUV mask M is situated. The process gases required to this end might also be guided e.g. locally (e.g. via a nozzle) into a vicinity of a point of incidence of the electron beam on the EUV mask M. For example, the apparatus 200 might comprise e.g. components of a scanning electron microscope which were supplemented with components that can enable an electron beam-induced deposition and/or etching.

However, as mentioned, the apparatus 200 need not be restricted to an electron beam but may also provide an ion beam as particle beam B. Further, an ion beam-induced etching and/or deposition might also be possible in analogous fashion using an apparatus 200.

Electron beams may in some examples provide the advantage that they typically do not contaminate the sample, they do not generally lead to foreign atoms being deposited within the sample. Also, they can be used to repair material on the sample or generally process the sample in a very fine manner.

Details of the apparatus 200 with regards to the application of the voltage to the EUV mask M are explained below. In one example, the apparatus 200 might comprise a mask repair apparatus which is configured to repair a mask (e.g. an EUV mask M).

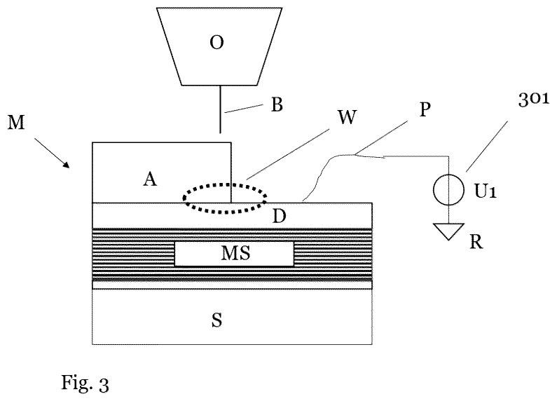

FIG. 3 schematically shows an application of a first voltage U1 to the lithography object (e.g. an EUV mask M) according to the invention. In this example, the first voltage U1 can be applied to the top side of the EUV mask M. For example, the first voltage U1 can be applied to the capping layer D and/or to an imaging structure A. By way of example, the first voltage U1 is applied to the capping layer D in FIG. 3.

For example, the first voltage U1 can be applied to the EUV mask M by way of a positionable contact element P (as described herein). For example, the positionable contact element P may comprise an electrically conductive scanning force probe (with e.g. a conductive tip).

For example, the apparatus 200 may be equipped with components of an atomic force microscope, in order to apply the first voltage U1 to the EUV mask. For example, the positionable contact element P can be positioned at any desired position on the top side of the EUV mask. Corresponding positioning mechanisms from atomic force microscopy, for example can be used. For example, the positionable contact element P may also comprise any desired electrically conductive beam element which is able to contact the capping layer D of the EUV mask M (and/or an imaging structure A on the EUV mask M).

As depicted schematically in FIG. 3, the positionable contact element may be coupled to a first voltage source 301 which can provide the first voltage U1. For example, the first voltage source 301 may comprise a voltage source unit for controlling the first voltage U1.

For example, the application of the first voltage to the top side of the EUV mask M as depicted in FIG. 3 might be advantageous if an application of the first voltage to the lower side (e.g. to the substrate S) of the EUV mask is unable to influence the particle beam.

In this respect, the following example is given: for example, the multilayer stack MS (and/or the substrate S) of the EUV mask can have a comparatively low electrical conductivity. For example, the multilayer stack MS (and/or the substrate S) may have an electrically insulating property. For example, the EUV mask M may represent a capacitor in this case since a type of electrical insulation may be present between substrate S and the capping layer D. If a predetermined voltage is applied to the lower side (e.g. to the substrate S) in this case, then this predetermined voltage cannot be applied to the opposite side, the top side of the EUV mask. Hence, it is therefore not (always) possible to ensure that the particle beam B is influenced by the first voltage.

According to the example in FIG. 3, this situation can be circumvented by virtue of the first voltage U1 being applied to the top side of the EUV mask M (e.g. to the capping layer D and/or the imaging structure A). Hence, it is possible to circumvent electrical insulation between the top and lower side of the EUV mask M in a targeted manner. Thus, for example, the first voltage can be applied to a side of the lithography object on which the electron beam B is incident.

For example, FIG. 3 also schematically depicts how the electron beam B emerges from the objective O of the apparatus 200. For example, the electron beam B can be used to process a work region W on the EUV mask M. For example, the work region W may comprise a pixel raster over which the electron beam B scans during the processing of the EUV mask M. For example, the pixel raster may comprise a repair shape for repairing the EUV mask M. For example, electron beam-induced deposition and/or etching may be implemented in the work region W in order to locally repair the EUV mask M. The electron beam B can be influenced in a targeted manner by the application of the first voltage U1 to the top side of the EUV mask M (e.g. to the capping layer D and/or to the imaging structure A). As mentioned, it is consequently possible to create a higher degree of freedom when repairing lithography masks. For example, within the scope of a mask repair, it may be useful to lower the acceleration of the electrons in the electron beam B and/or reduce the landing energy of the electrons during electron beam-induced etching or deposition. The first voltage U1 can also be used to improve an image recording of the EUV mask.

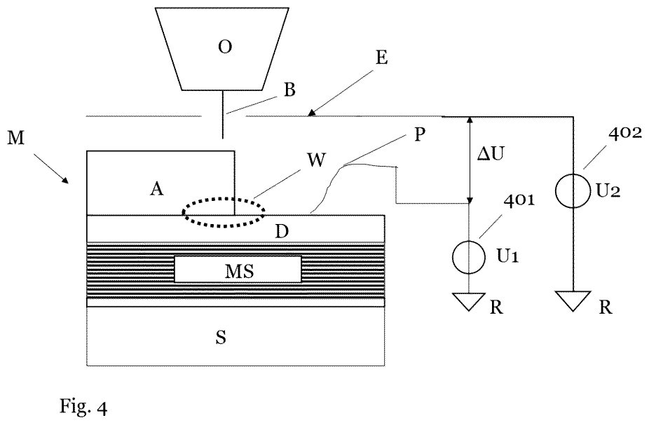

FIG. 4 schematically shows an application of a first voltage U1 and second voltage U2 to the lithography object according to the invention. The first voltage U1 can be applied in the same way as described for FIG. 3. Hence, in FIG. 4, the first voltage U1 is also applied to the side of the EUV mask M on which the electron beam B is incident. For example, the first voltage U1 is applied to the capping layer D of the EUV mask M in FIG. 4.

Additionally, the apparatus 200 may comprise an electrode element E. The electrode element E may comprise an opening through which the electron beam B is able to be incident on the EUV mask M. For example, the electrode element E may comprise a shielding element (as described herein). It is known that shielding elements are used passively for shielding an electric field during particle beam processing. In this case, the shielding element can be positioned as close as possible to the surface of the EUV mask, wherein the shielding element can fulfil its shielding functionality merely passively (without being at an electric potential).

According to the invention, a second voltage U2 can be applied to the electrode element E, in order to influence the particle beam B (e.g. an electron beam B). For example, the second voltage U2 can be determined with respect to a reference potential R. In FIG. 4, the second voltage U2 is depicted with respect to the potential of the first voltage U1, for example.

As described herein, the second voltage U2 can be used to control the voltage difference (or voltage drop) between electrode element E and the first voltage U1. For example, the application of the first voltage U1 (without the second voltage U2) may lead to certain phenomena. For example, such a case harbours the risk of flashovers from the EUV mask to surrounding components, and this may lead to the EUV mask being damaged. Further, the electric field caused by the first applied voltage U1 could be distorted by the topography of the EUV mask. This may impair the effectiveness of the field, for example for improving an imaging of the EUV mask M using the electron beam B. Further, a mechanical tilt of the EUV mask M relative to the objective O may lead to a field gradient, with the result that it is not always possible to ensure targeted influencing of the electron beam B.

For example, these effects can be reduced by virtue of setting the electrode element E at an electric potential. For example, the electrode element E can be connected to substantially the same potential as the EUV mask M. The aforementioned effects can be reduced in the now largely field-free space between EUV mask M and electrode element E, with the result that they for example no longer develop any (significant) effect. This example may comprise the case where the voltage difference ΔU between electrode element E and the EUV mask M (or between electrode element E and the contact element P), indicated in FIG. 4, is substantially zero (e.g. ΔU=0) For example, the first voltage U1 might also be applied to the electrode element E to this end, with the result that ΔU=U1−U1=0 applies.

For example, connecting the electrode element E to the potential of the first voltage U1 may be sufficient to this end. For example, the electrode element E may be connected to the first voltage source, which provides the first voltage U1. Thus, a separate voltage source for the voltage of the electrode element E is needed (but not mandatory) in such a case. In this example, the application of the second voltage to the electrode element E would comprise an application of the first voltage U1 to the electrode element.

For example, FIG. 4 illustrates another case, comprising a first voltage source 401 for the first voltage U1 and a second voltage source 402 for the second voltage U2. In this example, there can be a separate application of the second voltage U2 to the electrode element E. The first voltage U1 can also be applied separately to EUV mask M. To set the electrode element E to the same potential as the EUV mask M, the value of the second voltage U2 can be set to the value of the first voltage U1 in this case (e.g. U1=U2, and so ΔU=U2−U1=0). It is also evident from FIG. 4 that the first voltage U1 and the second voltage U2 can be applied with respect to the same reference potential (or can be defined as described herein).

To further optimize the influencing of the electron beam B, it is possible to apply an (e.g. small) effective voltage difference AU between electrode element E and EUV mask M (with ΔU≠0). For example, this can be implemented by way of a voltage difference ΔU between electrode element E and contact element P. For example, in this respect, the second voltage U2 could be chosen differently from the first voltage U1 in the illustrated example of FIG. 4 in order to bring about an effective voltage difference ΔU (e.g. U2>U1 or U2<U1). For example, this effective voltage difference (of ΔU≠0) can be used for a further improvement of the imaging of the EUV mask M. It is also conceivable that the voltage difference (of AU #0) is used e.g. for improving a particle beam-induced deposition or etching, in which the particle beam B is incident on the EUV mask M.

It should be observed that the aforementioned circuits for the application of the first and second voltage are chosen by way of example. The only circumstance required for the implementation of the invention is that the EUV mask M can be set at a first electric potential and the electrode element E can be set at a second electric potential. The potentials and the potential difference between the first and second electric potential can be implemented by way of intuitive mechanisms or circuits.

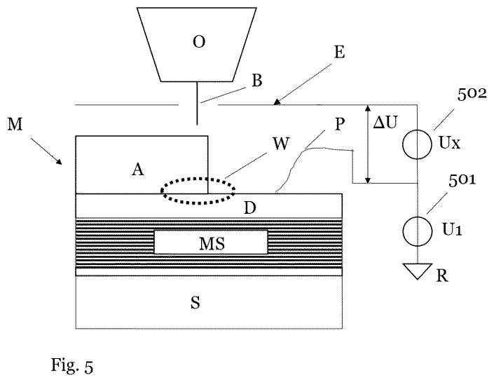

For example, a further circuit for applying the first and second voltage according to the invention is depicted in FIG. 5. In this example, the apparatus comprises a first voltage source 501 for applying the first voltage U1 to the EUV mask, like in the example of FIG. 4. However, a separate voltage source 502 may be installed between electrode element E and the first voltage source 501 in this example. The separate voltage source 502 could be installed such that the first voltage U1 is (substantially) applied to the electrode element E should the voltage Ux of the separate voltage source be zero. For example, the separate voltage source 502 can be installed such that the voltage Ux in the resultant circuit (substantially) corresponds to the voltage difference ΔU between electrode element E and EUV mask. In this circuit, the voltage difference ΔU could thus be applied directly by way of the separate voltage source 502. In this example, the second voltage U2 with respect to the reference potential R (as described herein) can for example correspond to the combination of the first voltage U1 and the voltage Ux (e.g. U2=U1+Ux). Thus, this circuit can merely implement the application of the first and second voltage U1, U2 in a different way.

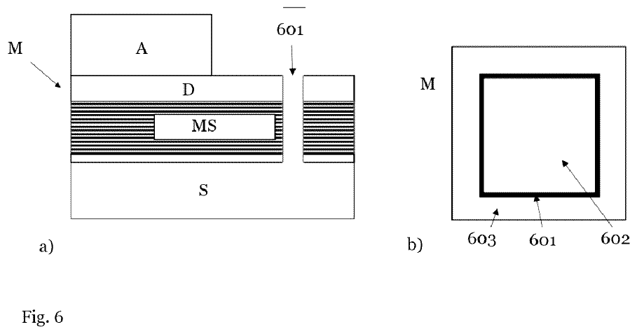

In the left partial image, FIG. 6 schematically shows a side view of an EUV mask which can be processed according to the invention and a corresponding plan view in the right partial image. For example, EUV masks M may comprise an edge 601 which surrounds an active used area 602 of the EUV mask M. Thus, the edge 601 can divide the EUV mask into an active used area 602 and an inactive area 603. The edge 601 can also be referred to as “image border”, for example. The used area 602 framed by the edge 601 may for example comprise the imaging structures A, which are required for semiconductor structuring. For example, the function of the edge 601 may be that of providing a defined optical boundary within which the imaging structures are present, in order to facilitate EUV lithography. In this context, the edge 601 may have a reflectivity that might be substantially lower than the reflectivity of an absorbing imaging structure A. Thus, the edge 601 may be comparatively strongly absorbent. For example, the edge 601 may be formed by an interruption in the multilayer stack MS, as indicated schematically in FIG. 6. To configure the edge 601, it might be possible for the capping layer D of the EUV mask M to be interrupted there; this is also schematically indicated in FIG. 6. Thus, the edge 601 of the EUV mask M might result in there being no electrical connection between the active used area 602 and the inactive area 603.

Therefore, the contact element P can be configured in positionable fashion (as described herein), with the result that the contact element P is able to come into contact with the active used area 602 (within the edge 601), for example in order to apply the first voltage U1 to the EUV mask. For example, the contact element P can be configured in the form of a scanning force probe, which can be driven to a position within the edge 602 using conventional means. In this case, the contact element P can be positioned independently of the positioning of the particle beam B. For example, the particle beam B can be directed at the centre of the EUV mask M. In this case, the contact element P can be positioned at any desired position on the EUV mask M without the point of incidence of the particle beam B on the EUV mask needing to be changed.

In this context, the creation of the edge 601 need not necessarily be standardized. It might also be the case that there is an electrical connection between active used area 602 and the inactive area 603 of the EUV mask M. In this case, e.g. the contact element P can contact the active used area 602 and/or the inactive area 603 in order to apply the first voltage U1 to the EUV mask M.

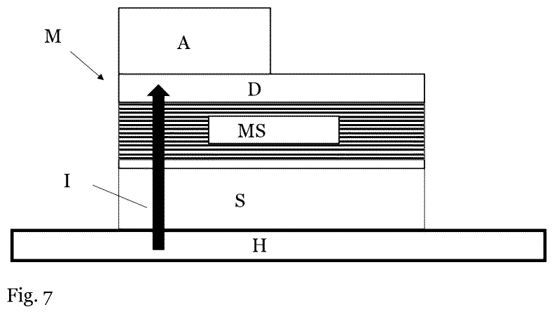

FIG. 7 finally shows, schematically, a further example of an application of a first voltage to the lithography object. The EUV mask M is attached to an object holder H in this example. For example, the object holder H may comprise a chuck configured to hold the EUV mask M stationarily. There may be an electrically conductive connection from the substrate S to the capping layer D (or an imaging structure A) of the EUV mask in the example of FIG. 7. For example, the electrically conductive connection may enable a current flow I between capping layer D and object holder H (as indicated schematically in FIG. 7). The object holder H may be configured to provide (e.g. in addition to a chucking function) a first voltage U1 on the substrate (e.g. via an additional electrode, as described herein). By applying the first voltage U1 to the object holder, the first voltage U1 can (substantially) also be applied to the top side of the EUV mask M (e.g. to the capping layer D) as a result of the electrically conductive connection between capping layer D and substrate S. Hence, a voltage at the object holder H can also be used to influence the particle beam B (as described herein).

The electrically conductive connection between capping layer D and substrate S in FIG. 7 may comprise e.g. an electrically conductive track between capping layer D and substrate S (e.g. the track can be designed such that it fulfils a similar function to a vertical interconnect access between capping layer D and substrate S). For example, the electrically conductive track may comprise a metal and/or semiconductor. For example, it is conceivable that the electrically conductive connection between capping layer D and substrate may be standardized as technology develops. In one example, it is also conceivable that the lithography object (e.g. a mask) comprises no layer (or multilayer stack) with insulating properties. Thus, the lithography object need not (necessarily) correspond to a capacitor, as explained here by way of example for the EUV mask. Thus, in such a case there is (not necessarily) a need for a special electrically conductive track which represents the electrically conductive connection between capping layer D and substrate S. In this case, e.g. one or more intermediate layers between capping layer D and substrate S of the lithography object may represent the electrically conductive connection.

The described mechanism of FIG. 7 can also be used in EUV masks M with an edge 601. As mentioned in relation to FIG. 6, the creation of the edge 601 need not necessarily be standardized. For example, in the case of an EUV mask M with an edge 601, it might also be the case that there is an electrical connection from the lower side of the EUV mask M to the top side of the EUV mask M. In such an example, the first voltage U1 can also be applied via the lower side of the EUV mask M, e.g. via an object holder H, as described for FIG. 7.

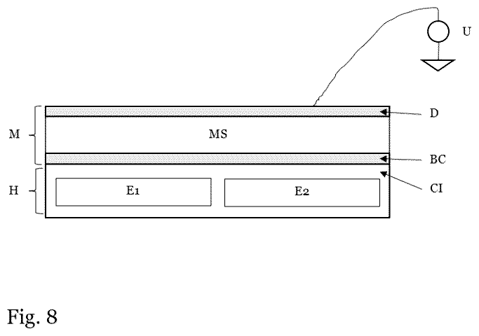

FIG. 8 schematically shows an application of a first voltage to the object, wherein the object holder H comprises an electrostatic chuck. It is evident that the electrostatic chuck H comprises an electrode E1 and an electrode E2. How the electrodes E1 and E2 are embedded in an insulator CI of the chuck H is also depicted schematically. Two opposing potentials may be applied to the electrodes E1 and E2 for the implementation of an electrostatic chucking function, with the result that the mask M is secured to the chuck H (by way of the resultant electric field). To enable the electrostatic chucking, the electric field emanating from the electrodes E1 and E2 can act on the mask M through the insulator CI. Thus, the electrodes E1 and E2 need not (necessarily) be in contact with the mask M. Within the scope of electrostatic chucking, a back side layer BC of the mask M can rest on the chuck H (or on the insulator CI of the chuck H). However, it is also conceivable that the substrate S can rest on the chuck H (or on the insulator CI of the chuck) (as depicted in the other figures). For example, the back side layer BC may adjoin the substrate S. From the example in FIG. 8, it is evident how the first voltage is applied to the top side of the mask, to the capping layer D (as described herein).

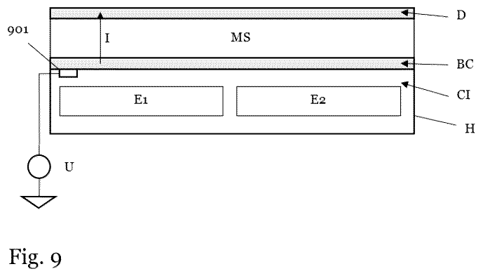

FIG. 9 schematically shows an application of a first voltage to the object via a first exemplary object holder H according to the invention. Like in FIG. 7, there is an electrically conductive connection from the substrate S (or from the back side layer BC of the mask M) to the capping layer D (or an imaging structure) in the example of FIG. 9. In this context, FIG. 9 may represent a detailed example of a chuck as described herein for FIG. 7. In addition to an electrostatic chucking function, the chuck of FIG. 9 can also enable an application of the first voltage to the mask. It is evident that the chuck H comprises an (additional) voltage electrode 901, for applying the first voltage to the mask M. The voltage electrode 901 can be in contact with the mask. For example, the voltage electrode 901 may be in contact with (or connected to) the substrate S and/or the back side layer BC. Consequently, the first voltage U can be applied to the capping layer D (or on the imaging structures) via the voltage electrode 901 on account of the electrically conductive connection from the back side to the front side of the mask M. In FIG. 9, the electrodes E1 and E2 can be considered to be floating with respect to the first voltage U. For example, the potentials of the electrodes E1 and E2 can be controlled in a dedicated voltage circuit. Thus, in summary, the electrodes E1 and E2 can serve to implement the chucking function, whereas the voltage electrode 901 serves to apply the first voltage (as described herein). It should also be mentioned that the object holder may comprise two or more pairs of electrostatic electrodes (and need not be restricted to the depicted one pair E1 and E2). For example, the object holder may also be configured in any possible way for causing an electrostatic chucking function (e.g. the object holder may also comprise one electrode for implementing the electrostatic chucking function or other means that are able to cause electrostatic chucking of the object).

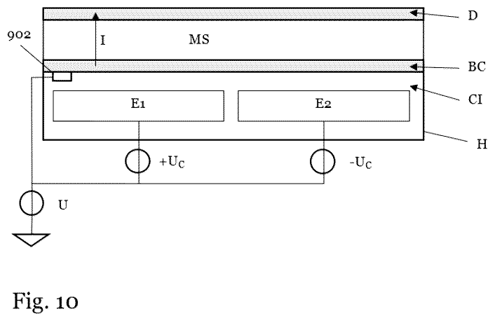

FIG. 10 schematically shows an application of a first voltage to the object via a second exemplary object holder according to the invention. In essence, FIG. 10 corresponds in terms of structure to that of FIG. 9. In FIG. 10, the electrode for applying the first voltage U is specified as voltage electrode 902. However, there is a different configuration of the electrodes E1 and E2 of the chuck H in relation to the voltage electrode 902 in FIG. 10. In FIG. 10, the electrodes E1 and E2 have a common point with the voltage circuit for applying the first voltage U. In respect of this common point, a voltage of +Uc can be applied to the electrode E1 and a voltage of-Uc can be specified at the electrode E2.

In summary, a further aspect of the invention can comprise the object holder described herein. Thus, the invention can relate to an object holder for fixing a lithography object, wherein the object holder comprises an electrode for influencing a particle beam incident on the object (as described herein). The object holder may also comprise electrodes for electrostatic fixation of the object. The electrostatic fixation electrodes may be embedded in an insulator. Embedding in the insulator can be such that the electrodes do not come into contact with the object for the purpose of electrostatic fixation.

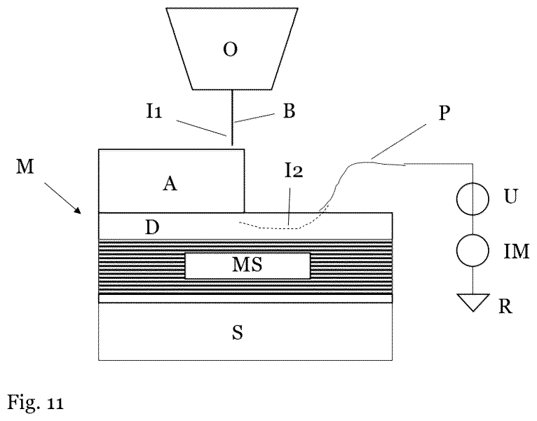

FIG. 11 schematically shows a method for testing a positionable contact element P with the aid of a particle beam B according to the invention. The illustrated method of FIG. 8 can for example be applied to test whether the contact element P is in contact with the lithography object (e.g. the EUV mask M). For example, this can be implemented before the first voltage U1 is applied to the EUV mask M via the contact element P. However, the illustrated method need not be restricted to testing the contact with lithography objects. Instead, the method can also be applied in order to test whether a contact element P is in contact with any (desired) object. Thus, the object might also be any desired sample (e.g. a (semiconductor-based) wafer, a microchip, a substrate, a biological sample, etc.) and not necessarily a lithography mask. For example, it may be necessary to process or examine any desired sample using a contact element P (e.g. using a scanning force probe). In this context, it may for example also be helpful to test whether the contact element P is in contact with the sample.

However, the functionality of the method will be described below on the basis of an EUV mask M, as depicted in FIG. 5. However, rather than the EUV mask M, this may also relate to any desired sample.

For example, EUV masks M can be very sensitive. Thus, the contact element P should not damage the EUV mask M when the contact element P comes into contact with the EUV mask. One option of attaining this lies in restricting the force exerted by the positionable contact element P on the mask. In one example, the contact element P comprises a beam element (e.g. a scanning force probe with an electrically conductive tip), which can be subject to open-loop and/or closed-loop control using means from atomic force microscopy. In this context, atomic force microscopy has disclosed numerous mechanisms for restricting the force exerted by e.g. the scanning force probe on an object. For example, this can be implemented by way of appropriate measuring and control loops. These may also be used in the method according to the invention.

According to the invention, a test as to whether there is a conductive connection from the contact element P to the EUV mask can also be implemented using the particle beam B. Further, the force exerted on the EUV mask M can also be restricted using the particle beam B.

For example, the contact element P can be coupled to an ammeter IM. For example, the ammeter IM can be installed to measure the current flow through the contact element P. For example, the ammeter IM is connected in series with the contact element P in FIG. 8. According to the method, the contact element P can e.g. be brought into a position in relation to the EUV mask M, at which the assumption is made that there should be contact between the contact element P and the EUV mask M.

Subsequently, the particle beam B (e.g. an electron beam) can be provided on the EUV mask with a certain particle beam current I1 (as indicated in FIG. 8). For example, the provision of the particle beam current B may cause an emission of particles from the material of the EUV mask M (e.g. an emission of secondary electrons, backscattered electrons, auger electrons, etc., as known from scanning electron microscopy for example). For example, these emitted particles can be used for imaging purposes. The particle beam B can also cause a current flow I2 via the EUV mask M into the contact element P (as indicated in FIG. 8). This current flow I2 can be used to test the contact quality with which the contact element P is in contact with the EUV mask M. For example, the assumption can be made that the current flow I2 tapped off at the contact element P depends on the quality of contact between the contact element P and the EUV mask M. In this case, according to the invention, the (absolute) value of the current flow I2 can be recorded quantitatively by the ammeter IM and can be used for the assessment of the contact quality. For example, a sufficiently present contact between contact element P and EUV mask M can be assumed in the case of (in terms of absolute value) a comparatively high current flow I2. For example, a poor or absent contact between contact element P and EUV mask M can be assumed in the case of (in terms of absolute value) a comparatively low current flow I2.

In one example, a comparison between the current flow I2 and a predetermined current threshold value I_{TH} can be used for the assessment of the contact quality. For example, there can be a comparison in terms of absolute value, in which the absolute value of the current flow I2 is compared with an absolute value of a current threshold value I_{TH} (or a positive current threshold value I_{TH}). For example, a first contact quality can be determined if the current flow I2 exceeds the current threshold value I_{TH} (I2>I_{TH} Or |I2|>|I_{TH}|). For example, the first contact quality may correspond to a contact quality that is sufficient for (reliably) applying the first voltage U1 to the EUV mask M. For example, a second contact quality can be determined if the current flow I2 (in terms of absolute value) drops below the current threshold value I_{TH} (I2<I_{TH} or |I2|<|I_{TH}|). For example, the second contact quality may correspond to a contact quality that is insufficient for (reliably) applying the first voltage U1 to the EUV mask M. For example, the contact element can be repositioned if the second contact quality was determined.

In one example, a comparison between a ratio of current flow I2 to particle flow I1 (e.g. I2/I1) and a predetermined ratio threshold value D can be used for the assessment of the contact quality. For example, a first contact quality can be determined if the ratio exceeds the ratio threshold value D (e.g. I2/I1>D). For example, the first contact quality may correspond to a contact quality that is sufficient for (reliably) applying the first voltage U1 to the EUV mask M. For example, a second contact quality can be determined if the ratio drops below the ratio threshold value D (e.g. I2/I1<D). For example, the second contact quality may correspond to a contact quality that is insufficient for (reliably) applying the first voltage U1 to the EUV mask M. For example, the contact element can be repositioned and/or a contact pressure of the contact element (with respect to the EUV mask) can be increased if the second contact quality was determined.

Further examples, helpful for understanding the invention are:
1. Method for processing an optical lithography object (M) with a particle beam (B), comprising:
   application of a first voltage (U1) to the object (M) with respect to a reference potential (R), in order to influence the particle beam (B).
2. Method according to Example 1, wherein the application of the first voltage (U1) causes an electric potential in a vicinity of a point of incidence of the particle beam.
3. Method according to Example 1 or 2, wherein influencing the particle beam (B) comprises a deceleration of the particles in the particle beam and/or a reduction in a landing energy of the particles in the particle beam.
4. Method according to any of Examples 1-3, wherein the first voltage (U1) comprises a negative voltage with respect to the reference potential (R).
5. Method according to any of Examples 1-4, wherein the first voltage is applied to a side of the object on which one or more imaging structures (A) of the object (M) are arranged.
6. Method according to any of Examples 1-5, wherein the first voltage is applied to a position of the object from where an electrically conductive connection leads to a vicinity of a point of incidence of the particle beam.
7. Method according to Example 6, wherein the electrically conductive connection comprises, at least in part, a capping layer (D) of the object (M), which may be adjoined by one or more imaging structures (A) of the object (M).
8. Method according to either of Examples 6 and 7, wherein the position of the object where the first voltage is applied comprises a part of the capping layer (D) of the object, which may be adjoined by one or more imaging structures (A) of the object, and/or wherein the position of the object where the first voltage is applied comprises a part of an imaging structure (A) of the object, wherein the imaging structure may adjoin a capping layer (D) of the object.
9. Method according to any of Examples 1-8, wherein the first voltage is applied via a positionable contact element (P).
10. Method according to Example 9, further comprising:
   provision of the particle beam (B) with a predetermined particle beam current (I1);
   determination of a contact quality of the contact element (P) based at least in part on the provided particle beam (B) and an electric current (I2) which flows through the contact element (P).
11. Method according to any of Examples 1-10, wherein the position of the object where the first voltage is applied is on a side of the object not containing any imaging structures and/or is on a substrate side of the object.
12. Method according to any of Examples 1-11, wherein the first voltage is applied via an electrically conductive object holder (H), to which the object is attached.
13. Method according to any of Examples 1-12, further comprising: application of a second voltage (U2) to an electrode element (E) with respect to the reference potential, wherein the electrode element is positioned between the object and a source of the particle beam and comprises an opening through which the particle beam can be incident on the work region.
14. Method according to Example 13, wherein the second voltage (U2) is applied so as to adapt an electric field between the object (M) and the electrode element (E).
15. Method according to Example 13 or 14, wherein the application of the second voltage (U2) comprises the second voltage substantially corresponding to the first voltage (U1).
16. Method according to either of Examples 13-14, wherein the application of the second voltage (U2) comprises the second voltage being different from the first voltage (U1).
17. Method according to any of Examples 13-16, wherein the electrode element (E) comprises a shielding element serving to shield the particle beam (B) from an electric field which may emanate from the object (M) when the latter is processed by the particle beam (B).
18. Method according to any of Examples 1-17, further comprising: creation and/or removal of a material of the object (M) based at least in part on the particle beam, preferably using at least one gas provided on the object.
19. Method according to any of Examples 1-18, wherein the method is used for repairing a defect of the object (M).
20. Method according to any of Examples 1-19, wherein the object comprises a mask for EUV lithography.
21. Method for testing a positionable contact element (P), comprising:
   provision of a particle beam (B) with a predetermined particle beam current (I1) on an object (M);
   determination of a contact quality of the positionable contact element (P) based at least in part on the provided particle beam and an electric current (I2) which flows through the positionable contact element.
22. Computer program comprising instructions for performing a method according to any of Examples 1-21 when the instructions are executed.
23. Apparatus for processing a lithography object (M) with a particle beam (B), comprising: means for applying a voltage (U1) to the object with respect to a reference potential (R), in order to influence the particle beam.
24. Apparatus according to Example 23, wherein the application means comprises a positionable contact element (P) and/or an object holder (H) and moreover comprises a voltage source (301, 401, 501) coupled to the contact element and/or the object holder.
25. Apparatus according to Example 23 or 24, wherein the application means is designed to apply, in terms of absolute value, a maximum voltage of 40 000 V, preferably 4000 V, more preferably 1000 V, and most preferably 100 V to the object with respect to the reference potential (R).
26. Apparatus according to Example 24 or 25, wherein the device comprises an ammeter (IM) coupled to the positionable contact element (P) and/or the object holder (H), wherein the ammeter is designed to measure a current of at least 0.5 pA, preferably at least 1 pA, more preferably at least 500 pA, and most preferably at least 1 nA through the positionable contact element and/or the object holder.
27. Apparatus comprising:
   a positionable contact element (P);
   means for providing a particle beam (B) with a predetermined particle beam current (I1) on an object (M);
   means for determining a contact quality of the positionable contact element (P) based at least in part on the provided particle beam and an electric current (I2) which flows through the positionable contact element.

What is claimed is:

1. An apparatus for interacting, with a particle beam, with a lithography object comprising:
means for applying a voltage to the object with respect to a reference potential, in order to influence the particle beam;
wherein the means for applying a voltage are adapted to apply the voltage to a side of the lithography object on which the particle beam is incident.

2. The apparatus of claim 1, wherein interacting, with the particle beam, with the lithography object, comprises at least one of:
inspecting, with the particle beam, the lithography object; and
processing, with the particle beam, the lithography object.

3. The apparatus of claim 1, wherein the particle beam comprises an electron beam.

4. The apparatus of claim 1, wherein the means for applying comprises a positionable contact element and/or an object holder and moreover comprises a voltage source coupled to the contact element and/or the object holder.

5. The apparatus of claim 1, wherein the means for applying is designed to apply, in terms of absolute value, a maximum voltage of 40 000 V to the object with respect to the reference potential.

6. The apparatus of claim 1, wherein the device comprises an ammeter coupled to the positionable contact element and/or the object holder, wherein the ammeter is designed to measure a current of at least 0.5 pA through the positionable contact element and/or the object holder.

7. An apparatus comprising:
a positionable contact element;
means for providing a particle beam with a predetermined particle beam current on an object; and
means for determining a contact quality of the positionable contact element based at least in part on the provided particle beam and an electric current which flows through the positionable contact element.

8. A method for interacting, with a particle beam, with an optical lithography object, comprising:
applying a first voltage to the object with respect to a reference potential, in order to influence the particle beam;
wherein the first voltage is applied to a side of the object on which the particle beam is incident.

9. The method of claim 8, wherein interacting, with the particle beam, with the optical lithography object, comprises at least one of:
inspecting, with the particle beam, the lithography object; and
processing, with the particle beam, the lithography object.

10. The method of claim 8, wherein the application of the first voltage causes an electric potential in a vicinity of a point of incidence of the particle beam.

11. The method of claim 8, wherein influencing the particle beam comprises a deceleration of the particles in the particle beam and/or a reduction in a landing energy of the particles in the particle beam.

12. The method of claim 8, wherein the first voltage comprises a negative voltage with respect to the reference potential.

13. The method of claim 8, wherein one or more imaging structures of the object are arranged on the side of the object.

14. The method of claim 8, wherein the first voltage is applied to a position of the object from where an electrically conductive connection leads to a vicinity of a point of incidence of the particle beam.

15. The method of claim 14, wherein the electrically conductive connection comprises, at least in part, a capping layer of the object, which may be adjoined by one or more imaging structures of the object.

16. The method of claim 14, wherein the position of the object where the first voltage is applied comprises a part of the capping layer of the object, which may be adjoined by one or more imaging structures of the object, and/or wherein the position of the object where the first voltage is applied comprises a part of an imaging structure of the object, wherein the imaging structure may adjoin a capping layer of the object.

17. The method of claim 8, wherein the first voltage is applied via a positionable contact element.

18. The method of claim 17, further comprising:
provision of the particle beam with a predetermined particle beam current; and
determination of a contact quality of the contact element based at least in part on the provided particle beam and an electric current which flows through the contact element.

19. The method of claim 8, wherein the position of the object where the first voltage is applied is on a side of the object not containing any imaging structures and/or is on a substrate side of the object.

20. The method of claim 8, wherein the first voltage is applied via an electrically conductive object holder, to which the object is attached.

21. The method of claim 8, further comprising:
application of a second voltage to an electrode element with respect to the reference potential, wherein the electrode element is positioned between the object and a source of the particle beam and comprises an opening through which the particle beam can be incident on the work region.

22. The method of claim 21, wherein the second voltage is applied so as to adapt an electric field between the object and the electrode element.

23. The method of claim 21, wherein the application of the second voltage comprises the second voltage substantially corresponding to the first voltage.

24. The method of claim 21, wherein the application of the second voltage comprises the second voltage being different from the first voltage.

25. The method of claim 21, wherein the electrode element comprises a shielding element serving to shield the particle beam from an electric field which may emanate from the object when the latter interacts with the particle beam.

26. The method of claim 8, further comprising:
creating and/or removing of a material of the object based at least in part on the particle beam.

27. The method of claim 8, wherein the method is used for repairing a defect of the object.

28. The method of claim 8, wherein the object comprises a mask for EUV lithography.

29. A method for testing a positionable contact element, comprising:
provision of a particle beam with a predetermined particle beam current on an object; and
determination of a contact quality of the positionable contact element based at least in part on the provided particle beam and an electric current which flows through the positionable contact element.

30. A computer program comprising instructions for performing a method according to claim 8 when the instructions are executed.
